(19) United States
(12) Patent Application Publication
(10) Pub. No.: US 2025/0363619 A1
(43) Pub. Date: Nov. 27, 2025

(54) SEMICONDUCTOR PATTERN MEASUREMENET DEVICE AND METHOD OF OPERATION

(71) Applicant: SAMSUNG ELECTRONICS CO., LTD., Suwon-si (KR)

(72) Inventors: JINCHOEL CHOI, Suwon-si (KR); Dongeun KIM, Suwon-si (KR)

(73) Assignee: SAMSUNG ELECTRONICS CO., LTD., Suwon-si (KR)

(21) Appl. No.: 18/974,342

(22) Filed: Dec. 9, 2024

(30) Foreign Application Priority Data
May 23, 2024 (KR) 10-2024-0067222

(51) Int. Cl. G06T 7/00

(52) U.S. Cl. CPC G06T 7/001; G06T 2207/10061; G06T 2207/20048; G06T 2207/20221; G06T 2207/30148

(57) ABSTRACT

Provided is a semiconductor pattern measurement method including obtaining a scanning electron microscope (SEM) image of a measurement target pattern on a surface of a wafer and including a repetitive pattern, generating a first image by performing a two-dimensional Fourier transform on the SEM image, generating a second image by merging a plurality of the first image, and obtaining information on repetition period of the repetitive pattern based on the second image.

### CROSS-REFERENCE TO RELATED APPLICATION

This application claims priority to Korean Patent Application No. 10-2024-0067222 filed in the Korean Intellectual Property Office on May 23, 2024, the entire contents of which are incorporated herein by reference.

### BACKGROUND

### 1. Field

Embodiments of the present disclosure relate to a semiconductor pattern measurement device and an operation method thereof.

### 2. Description of Related Art

With the recent development of information technology, semiconductor devices are being used in various devices in our environment. In addition, as the performance and function of the semiconductor device used are improved, the structures of semiconductor devices are becoming more refined, and a more precise manufacturing technology is required. In order to manufacture a semiconductor device that may achieve the required performance when manufacturing a semiconductor device such as a semiconductor wafer, when necessary to form a nanometer-level fine wafer pattern on the wafer surface. In addition, technology is needed to obtain information about the pattern formed on the wafer surface and accurately determine whether a fine wafer pattern has been formed according to design data. Therefore, a method to efficiently acquire information about the pattern formed on the wafer surface is required.

### SUMMARY

One or more embodiments provide a semiconductor pattern measurement device that efficiently minimizes pattern distribution when acquiring information about a pattern formed on a wafer surface, and an operation method thereof.

According to an aspect of one or more embodiments, there is provided a semiconductor pattern measurement method including obtaining a scanning electron microscope (SEM) image of a measurement target pattern on a surface of a wafer and including a repetitive pattern, generating a first image by performing a two-dimensional Fourier transform on the SEM image, generating a second image by merging a plurality of the first image, and obtaining information on repetition period of the repetitive pattern based on the second image.

According to another aspect of one or more embodiments, there is provided a semiconductor pattern measurement method including obtaining a reference image having a first resolution corresponding to a measurement target pattern on a surface of a wafer and including a repetitive pattern, obtaining a scanning electron microscope (SEM) image having a second resolution that is lower than the first resolution corresponding to the measurement target pattern, generating a first image by performing a two-dimensional Fourier transform on the SEM image, generating a second image by merging a plurality of the first image, and obtaining a repetition period of the repetitive pattern in the second image based on information on a reference repetition period of the repetitive pattern obtained from the reference image.

According to still another aspect of one or more embodiments, there is provided A semiconductor pattern measurement device including a scanning electron microscope (SEM) configured to obtain an SEM image on a surface of a wafer, on which a measurement target pattern including a repetitive pattern is formed, and at least one processor operatively connected to the SEM, wherein the at least one processor is configured to obtain an SEM image of the measurement target pattern on the surface of the wafer and including the repetitive pattern through the SEM, generate a first image by performing a two-dimensional Fourier transform on the SEM image, generate a second image by merging a plurality of the first image, and obtain information on a repetition period of the repetitive pattern based on the second image.

### BRIEF DESCRIPTION OF DRAWINGS

Embodiments will be more clearly understood from the following detailed description taken in conjunction with the accompanying drawings in which:

FIG. 1 is a block diagram of a semiconductor pattern measurement device according to one or more embodiments;

FIG. 2 shows an scanning electron microscope (SEM) in the semiconductor pattern measurement device according to one or more embodiments;

FIG. 3 is a flowchart of an operation method of the semiconductor pattern measurement device according to one or more embodiments;

FIG. 4 is a flowchart of an operation method of a semiconductor pattern measurement device according to one or more other embodiments;

FIG. 5 shows a reference image of a surface of a wafer where a measurement target pattern is formed according to one or more embodiments;

FIG. 6 shows an SEM image on a wafer surface where a measurement target pattern is formed according to one or more embodiments;

FIG. 7 shows a first image obtained by performing a two-dimensional Fourier transform on the SEM image of FIG. 6;

FIG. 8 shows a second image obtained by merging a plurality of the first image of FIG. 7;

FIG. 9 shows a position of a peak generated by the repetitive pattern of the measurement target pattern according to one or more embodiments; and

FIG. 10 shows a computer device that implements a semiconductor pattern measurement device according to one or more embodiments.

### DETAILED DESCRIPTION

Hereinafter, with reference to accompanying drawings, various embodiments will be described in detail and thus a person of an ordinary skill may easily practice them in the technical field to which the present disclosure belongs. The present disclosure may be embodied in many different forms and is not limited to the embodiments described herein.

In order to clearly explain the present disclosure, parts irrelevant to the description have been omitted, and the same reference numerals should be attached to the same or similar constituent elements throughout the specification.

In addition, since the size and thickness of each component shown in the drawing is arbitrarily shown for convenience of description, the present disclosure is not necessarily limited to the shown. In the drawings, the thickness of layers, films, panels, regions, etc., are exaggerated for clarity. In addition, in the drawing, for convenience of explanation, the thickness of some layers and regions is exaggerated.

It will be understood that when an element such as a layer, film, region, or substrate is referred to as being “on” another element, it may be directly on the other element or intervening elements may also be present. In contrast, when an element is referred to as being “directly on” another element, there are no intervening elements present. Further, throughout the specification, the word “on” a target element will be understood to mean positioned above or below the target element, and will not necessarily be understood to mean positioned “at an upper side” based on an opposite to gravity direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

In addition, terms including “portion, “unit”, “module”, and the like disclosed in the specification mean a unit that processes at least one function or operation and this may be implemented by hardware or software or a combination of hardware and software. In addition, a plurality of “ . . . module”, a plurality of “ . . . unit”, or a plurality of “ . . . module” may be integrated into at least one module and implemented with at least one processor, except for “ . . . portion”, “ . . . unit”, or “ . . . module” that needs to be implemented with specific hardware.

In this specification, “transmission” or “provision” may include not only transmitting or providing directly, but also indirectly transmitting or providing through another device or using a bypass path.

Expressions written as singular in this specification may be interpreted as singular or plural, unless explicit expressions such as “one” or “single” are used.

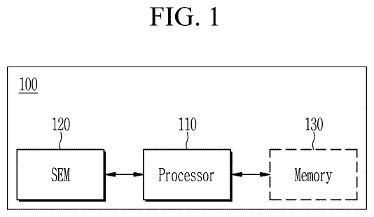

Hereinafter, referring to FIG. 1, a semiconductor pattern measurement device according to one or more embodiments will be described.

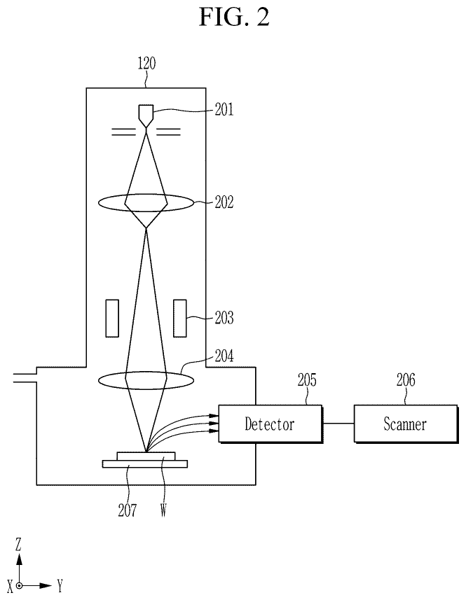

FIG. 1 is a block diagram of a semiconductor pattern measurement device according to one or more embodiments. FIG. 2 shows an SEM according to one or more embodiments.

Referring to FIG. 1 and FIG. 2, a semiconductor pattern measurement device 100 according to one or more embodiments may include at least one processor 110, a scanning electron microscope (SEM) 120, and a memory 130. In one or more embodiments, at least one of the above-mentioned components may be omitted in the semiconductor pattern measurement device 100 or the semiconductor pattern measurement device 100 may additionally include other components (e.g., communication circuit, display, input device).

According to one or more embodiments, at least one processor 110 may be operatively connected with the SEM 120 and the memory 130. The processor 110 may control the operation of the semiconductor pattern measurement device 100 by controlling at least one other component of the semiconductor pattern measurement device 100 connected to the processor 110.

According to one or more embodiments, the processor 110 may execute instructions stored in the memory 130. The processor 110 may execute applications stored in the memory 130. Each application may be a set of instructions. The processor 110 may execute instructions stored in the memory 130 to enable the semiconductor pattern measurement device 100 to perform operations described later. The operations described below as being performed by the processor 110 may be performed by the processor 110 and/or at least one other component of the semiconductor pattern measurement device 100 connected to the processor 110, and therefore it may be understood that they are performed by the semiconductor pattern measurement device 100.

According to one or more embodiments, the SEM 120 may be configured to measure wafers. According to one or more embodiments, the SEM 120 may measure wafers on which a manufacturing process of a semiconductor device has been performed using a scanning method. According to one or more embodiments, the SEM 120 may acquire (obtain) SEM images by photographing required pattern portions at various positions on the wafer.

According to one or more embodiments, the SEM 120 emits an input electron beam to a wafer and detects emission electrons emitted from the wafer by the interaction between the input electron beam and the wafer, thereby evaluating a manufacturing process of a semiconductor device performed on the wafer.

Referring to FIG. 2, the SEM 120 may include an electron gun 201, a condenser lens 202, a scanning coil 203, an objective lens 204, a detector 205, a scanner 206, and a stage 207.

The electron gun 201 may generate an electron beam. For example, a short-key type or heat-field emission-type electron gun may be used. An electron beam may be emitted by applying an acceleration voltage to the electron gun 201. The condenser lens 202 may serve to focus and accelerate the electron beam. For example, the condenser lens 202 may include an electromagnetic lens.

The scanning coil 203 may scan an electron beam one-dimensionally or two-dimensionally onto a specimen, that is, a sample wafer W. The objective lens 204 may focus the electron beam deflected by the scanning coil 203 on an upper surface of the sample wafer W. For example, the objective lens 204 may include an electromagnetic lens.

The detector 205 may detect (obtain) back scattered electrons when an electron beam is emitted to the sample wafer W and/or secondary electrons generated from the sample wafer W by electron beam irradiation. The scanner 206 may analyze a detection signal for electrons detected from the detector 205 and generate an image of a PR pattern or wafer pattern on the sample wafer W. In addition, the scanner 206 may control a scan direction of the electron beams by applying a high-frequency control signal to the scanning coil 203.

The stage 207 is a location where the sample wafer W is placed, and the sample wafer W may be supported by being placed on an upper surface of the stage 207. The stage 207 may move the sample wafer W in the left-right direction or up-down direction through straight line movement in the left-right direction or up-down direction.

According to one or more embodiments, the SEM 120 may further include a controller configured to control each optical element included in the SEM 120. The controller may be configured to generate a signal for controlling at least one of, for example, oscillation of the electron gun 201, operation of the condenser lens 202, operation of the scanning coil 203, operation of the objective lens 204, operation of the detector 205, operation of the scanner 206, or the stage 207.

According to one or more embodiments, the memory 130 may store data used by at least one component (e.g., the processor 110) or acquired from at least one component (e.g., the SEM 120) of the semiconductor pattern measurement device 100. The memory 130 may store instructions executed by at least one processor 110. For example, the memory 130 may store information about the repetition period of the repetitive pattern determined (or calculated/obtained) by the processor 110. According to one or more embodiments, the repetition period of the repetitive pattern stored in the memory 130 may be used as reference data after being stored.

According to one or more embodiments, the memory 130 may store data acquired through the SEM 120. For example, the memory 130 may store an SEM image acquired through the SEM 120. For example, the memory 130 may store the SEM image acquired for the measurement target pattern consisting of a repetitive pattern through the SEM 120.

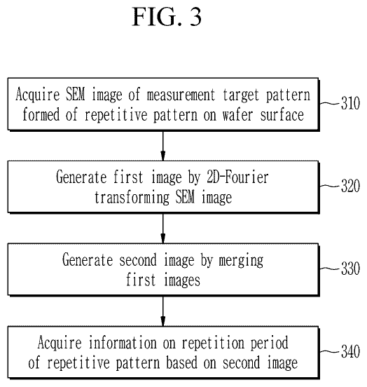

According to one or more embodiments, the memory 130 may store a reference image for the pattern to be measured before acquiring a large area SEM image, which will be described later with reference to operation 310 of FIG. 3. For example, the memory 130 may store a reference image of first resolution (e.g., high resolution (HR)) for the pattern to be measured acquired through the SEM 120. The reference image for the pattern to be measured may be acquired once for the first time through the SEM 120 and stored in the memory 130.

According to one or more embodiments, the memory 130 may store information about the target pitch of a repetitive pattern calculated through a reference image. In the present disclosure, “target pitch” may be referred to as “reference repetition period.”

For example, target pitch may indicate a length between centers of a repetitive pattern along one direction on a reference image or a separation distance between the centers. According to one or more embodiments, the memory 130 may store information about the target pitch of the repetitive pattern calculated through the reference image. For example, the target pitch may include at least one of an X-axis pitch Pₓ of the repetitive pattern in a first direction (X-axis direction) and a Y-axis pitch P_{y} of the repetitive pattern in a second direction (Y-axis direction).

According to one or more embodiments, the memory 130 may store an SEM image with second resolution (e.g., low resolution, LR) for the pattern to be measured acquired through the SEM 120. Here, the second resolution may be lower than the first resolution.

According to one or more embodiments, the memory 130 may store information about the pitch of the repetitive pattern that is determined (or acquired) based on the SEM image of the pattern to be measured. In the present disclosure, “pitch” may be referred to as “repetition period.”

For example, pitch may be calculated (obtained) based on the second image and may refer to the length between the centers of the repetitive pattern along one direction or the separation distance between the centers. According to one or more embodiments, the memory 130 may store information about the pitch of the repetitive pattern calculated through the SEM image. For example, the target pitch may include at least one of an X-axis pitch Pₓ of the repetitive pattern in a first direction (X-axis direction) and a Y-axis pitch P_{y} of the repetitive pattern in a second direction (Y-axis direction).

FIG. 3 is a flowchart of an operation method of the semiconductor pattern measurement device according to one or more embodiments.

Each operation in FIG. 3 may be performed sequentially, but is not necessarily performed sequentially. For example, the order of each operation may be changed, and at least two operations may be performed in parallel. In one or more embodiments, some of the operations shown in FIG. 3 may be omitted, some operations may be integrated, the order of some operations may be changed, or other operations may be added.

Referring to FIG. 3, in the operation 310, a semiconductor pattern measurement device (e.g.: semiconductor pattern measurement device 100 of FIG. 1) is formed on a surface of the wafer and an SEM image of the pattern to be measured, which consists of a repetitive pattern, may be acquired.

According to one or more embodiments, the semiconductor pattern measurement device 100 may acquire an SEM image on the wafer through an SEM (e.g., SEM 120 in FIG. 1). According to one or more embodiments, the SEM 120 may acquire an SEM image in which a moiré pattern appears through large area measurement of the measurement target pattern formed on the wafer surface. Moiré effect may be caused by the repetitive pattern included in the pattern to be measured.

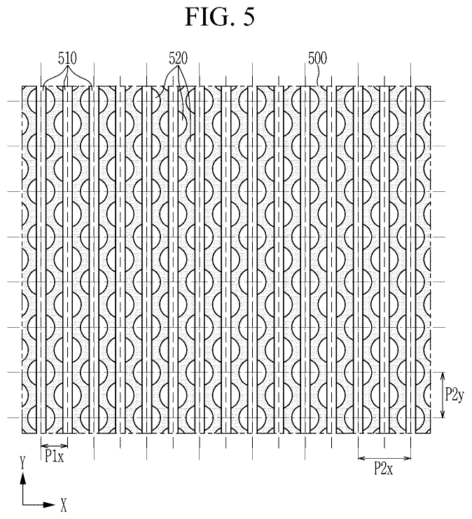

According to one or more embodiments, the pattern to be measured may be formed of a repetitive pattern. According to one or more embodiments, the pattern to be measured may be formed of the same pattern repeated in a two-dimensional direction. For example, the pattern to be measured may be repeated in a first direction (e.g., the first direction (X-axis direction) in FIG. 5) and/or a second direction (e.g., the second direction (Y-axis direction) in FIG. 5) on the two-dimensional image. For example, the pattern to be measured may be repeated in the first direction (X-axis direction) on a two-dimensional image. In addition, for example, the pattern to be measured may be repeated in the second direction (Y-axis direction) on a two-dimensional image. Further, for example, the pattern to be measured may be repeated in the first direction (X-axis direction) and the second direction (Y-axis direction) on a two-dimensional image.

According to one or more embodiments, the shape of the pattern to be measured may include, for example, a straight-line shape or a circular shape. However, embodiments are not limited thereto, and the form of the repetitive pattern forming the pattern to be measured may change according to various embodiments. For example, a repetitive pattern may be formed of a bar shape. For example, the repetitive pattern may be formed of a bar shape with a slope in one direction.

According to one or more embodiments, in operation 320, the semiconductor pattern measurement device 100 may generate a first image by performing a two-dimensional Fourier transform on the SEM image.

According to one or more embodiments, the semiconductor pattern measurement device 100 may obtain the first image by performing a two-dimensional Fourier transform on SEM image data acquired through the SEM 120. According to one or more embodiments, the semiconductor pattern measurement device 100 may use a fast Fourier transform (FFT) method to calculate the phase of the peak. In the present disclosure, the first image may correspond to 2-dimensional FFT data obtained by performing 2-dimensional Fourier transform on the SEM image.

According to one or more embodiments, the semiconductor pattern measurement device 100 may acquire orientation information and/or periodicity information of a pattern to be measured based on the first image. For example, the semiconductor pattern measurement device 100 may analyze the first image to determine whether the pattern to be measured is composed of a repetitive pattern.

According to one or more embodiments, when the pattern to be measured is formed of a repetitive pattern, frequency components may be observed at a specific position on the first image. For example, the frequency component may include a pattern in the form of dots or lines. According to one or more embodiments, the first image may include a plurality of frequency components having a two-dimensional array centered on the midpoint. In addition, the first image may have symmetry with respect to the midpoint.

According to one or more embodiments, the semiconductor pattern measurement device 100 may acquire directionality and/or periodicity information of a pattern to be measured based on the first image. According to one or more embodiments, when the pattern to be measured has periodicity, symmetrical frequency components may be detected using the midpoint as a reference in the first image. For example, in the case of a repetitive pattern that repeats with a specific period in the first direction (X-axis direction), frequency components may be detected on the X-axis. In addition, for example, in the case of a repetitive pattern that repeats with a specific period in the second direction (Y-axis direction), frequency components may be detected on the Y-axis. Further, for example, in the case of a repetitive pattern that repeats with a specific period in the first direction (X-axis direction) and the second direction (Y-axis direction), frequency components may be detected on any axis between the X-axis and Y-axis. In other words, an arbitrary axis may be defined as an axis forming a predetermined angle with the X-axis or Y-axis.

According to one or more embodiments, in operation 330, the semiconductor pattern measurement device 100 may generate a second image by merging a plurality of first images.

According to one or more embodiments, the semiconductor pattern measurement device 100 may generate aliasing by using an undersampling method. When using the undersampling method, an input signal frequency exceeds the boundary of the Nyquist frequency, and thus the semiconductor pattern measurement device 100 according to one or more embodiments reconstructs the first image to determine the exact position of the peak, thereby generating a second image.

According to one or more embodiments, the semiconductor pattern measurement device 100 may generate the second image by merging a plurality of first images in order to detect peaks generated by the repetitive pattern of the pattern to be measured. For example, the semiconductor pattern measurement device 100 may generate the second image by merging the same first images. For example, the semiconductor pattern measurement device 100 may generate identical first images by copying one first image. In the present disclosure, the second image may correspond to two-dimensional FFT data that is a merge of the same first images.

According to one or more embodiments, the semiconductor pattern measurement device 100 may merge the same first images. For example, the semiconductor pattern measurement device 100 may merge multiple first images using a stitching method. For example, the semiconductor pattern measurement device 100 may generate the second image by connecting the boundary of the first image. For example, the semiconductor pattern measurement device 100 may generate a 3×3 second image by merging nine first images using a stitching method.

According to one or more embodiments, in operation 340, the semiconductor pattern measurement device 100 may acquire information about the repetition period of the repetitive pattern based on the second image.

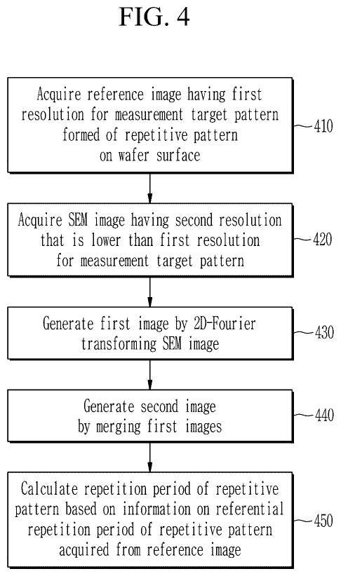

According to one or more embodiments, the semiconductor pattern measurement device 100 may detect a peak on the second image. According to one or more embodiments, the semiconductor pattern measurement device 100 may detect the position of the peak on the second image. According to one or more embodiments, the semiconductor pattern measurement device 100 may detect a peak on the second image based on information previously stored in a memory (e.g., the memory 130 in FIG. 1) regarding the pattern to be measured. Detailed information on detecting peaks based on previously stored information about the pattern to be measured will be described with reference to FIG. 4 later.

For reference, frequency is defined as 1/period, and therefore when the period is a distance, frequency may be expressed as 1/distance unit. Accordingly, the repetition period of the repetitive pattern may be calculated based on the frequency corresponding to the detected peak. In the present disclosure, “repetition period” may be referred to as “pitch.”

“Pitch” may indicate a length between centers along one direction of certain configurations or a separation distance between centers.

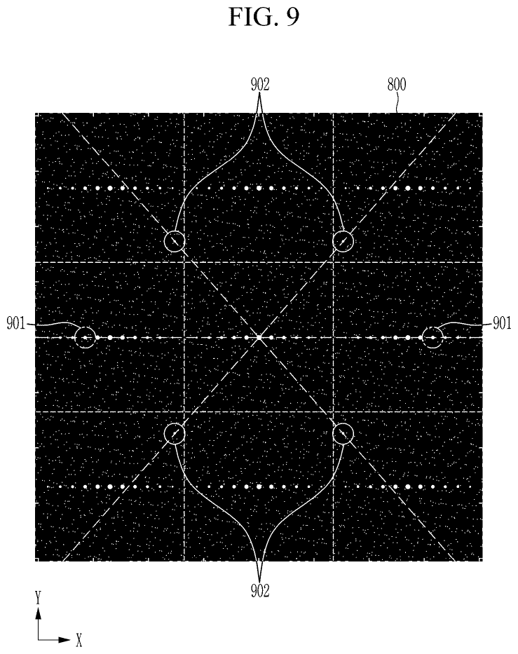

According to one or more embodiments, the semiconductor pattern measurement device 100 may calculate the X-axis pitch (Pₓ) in first direction (X-axis direction) and/or the Y-axis pitch (P_{y}) in the second direction (Y-axis direction) for the repetitive pattern based on the phase of the peak detected in the second image. Detailed description related to calculating the pitch of the repetitive pattern will be provided later with reference to FIG. 9.

According to one or more embodiments, the semiconductor pattern measurement device 100 may repeatedly perform the operations of FIG. 3 until a more accurate data on the position or shape of the peak is obtained. For example, after obtaining information about the repetition period in operation 340, the semiconductor pattern measurement device 100 may return to the operation 310 and perform repeatedly the operations in FIG. 3. In this case, a region of the pattern to be measured may change. That is, the semiconductor pattern measurement device 100 may change a region of the measurement target pattern after acquiring information about the repetition period and detect the peak for the changed region of the measurement target pattern.

As described above, in the semiconductor pattern measurement device according to the present disclosure, the accuracy of peak detection may be improved by changing the region of the pattern to be measured and repeating operations 310 to 340.

As described above, in the semiconductor pattern measurement device according to the present disclosure, the speed of measuring the pattern may be improved by acquiring a large area image of the pattern to be measured. For example, by measuring the wafer surface with large area field of view (FoV), the wafer may be quickly measured as a surface unit.

In addition, as described above, in the semiconductor pattern measurement device according to the present disclosure, noise between images may be minimized compared to the existing method of dividing the region into an acquisition method by acquiring a large area image for the pattern to be measured.

In addition, as described above, in the semiconductor pattern measurement device according to the present disclosure, damage caused by electrons emitted onto the wafer may be minimized by minimizing the number of SEM images acquired for the wafer surface.

FIG. 4 is a flowchart of an operation method of a semiconductor pattern measurement device according to one or more other embodiments. In the following embodiments, description that overlaps with description provided with reference to FIG. 3 may be omitted or simplified.

Each operation in FIG. 4 may be performed sequentially, but is not necessarily performed sequentially. For example, the order of each operation may be changed, and at least two operations may be performed in parallel. In one or more embodiments, some of the operations shown in FIG. 4 may be omitted, some operations may be combined, the order of some operations may be changed, or other operations may be added.

Referring to FIG. 4, in operation 410, a semiconductor pattern measurement device (e.g., the semiconductor pattern measurement device 100 in FIG. 1) is formed on a surface of a wafer and may acquire a reference image with first resolution (e.g., high resolution) for a measurement target pattern formed of a repetitive pattern. According to one or more embodiments, the semiconductor pattern measurement device 100 may acquire a reference image for a surface region of the wafer within a first FoV (e.g., local region).

According to one or more embodiments, the semiconductor pattern measurement device 100 may acquire an image on a wafer through an SEM (e.g., the SEM 120 in FIG. 1). According to one or more embodiments, the SEM 120 may acquire a reference image with first resolution (e.g., high resolution) for the pattern to be measured formed on the wafer surface.

In the present disclosure, the reference image may correspond to an SEM image with the first resolution (e.g., high resolution) for the wafer surface.

In the present disclosure, the reference image may correspond to an SEM image of a first region (e.g., a narrow region) of the wafer surface. According to one or more other embodiments, the reference image may correspond to the SEM image of the wafer surface region within the first FoV. For example, the first region has a first width (e.g. a narrow width) in a first direction (e.g., the first direction (X-axis direction) in FIG. 5) and/or in a second direction (e.g., the second direction (Y-axis direction) in FIG. 5).

According to one or more embodiments, the semiconductor pattern measurement device 100 may acquire information about a reference repetition period (or target pitch) of the pattern to be measured based on the reference image. For example, the semiconductor pattern measurement device 100 may obtain information about a one-dimensional or two-dimensional reference repetition period of the repetitive pattern based on the reference image.

For example, the semiconductor pattern measurement device 100 may obtain information about the reference repetition period based on a distance between each repetitive pattern included in the reference image. For example, the shape of a repetitive pattern may include a straight-line shape or a circle shape. However, embodiments are not limited thereto, and the shape of the pattern to be measured may vary depending on various embodiments.

According to one or more embodiments, the repetitive pattern may have any spacing pitch on a two-dimensional image along the first direction (e.g., the first direction (X-axis direction) in FIG. 5) and/or in the second direction (e.g., the second direction (Y-axis direction) in FIG. 5), respectively. For example, the repetitive pattern may be arranged to have an X-axis pitch (Pₓ) along the first direction (X-axis direction). In this case, the repetitive pattern may not be arranged repeatedly in any direction other than the first direction (X-axis direction).

In addition, for example, the repetitive pattern may be arranged to have a Y-axis pitch (P_{y}) along the second direction (Y-axis direction). In this case, the repetitive pattern may not be arranged repeatedly in any direction other than the second direction (Y-axis direction).

In addition, for example, the repetitive pattern may be arranged to have equal pitches along the first direction (X-axis direction) and the second direction (Y-axis direction). That is, the repetitive pattern may be arranged to have an X-axis pitch (Pₓ) along the first direction (X-axis direction) and a Y-axis pitch (P_{y}) along the second direction (Y-axis direction).

According to one or more embodiments, the semiconductor pattern measurement device 100 may store a reference image acquired through the SEM 120 in a memory (e.g., the memory 130 in FIG. 1). According to one or more embodiments, the semiconductor pattern measurement device 100 may store information about the reference repetition period of a pattern to be measured acquired based on a reference image in the memory 130. For example, the semiconductor pattern measurement device 100 may store the X-axis pitch (Pₓ) in the first direction (X-axis direction) and/or the Y-axis pitch (P_{y}) in the second direction (Y-axis direction) for the repetitive pattern in the memory 130.

According to various embodiments, when the X-axis pitch (Pₓ) and/or Y-axis pitch (P_{y}) is pre-stored or a user (e.g. worker) inputs the X-axis pitch (Pₓ) and/or Y-axis pitch (P_{y}) through an input device, the operation 410 may be omitted.

According to one or more embodiments, in operation 420, the semiconductor pattern measurement device 100 may acquire an SEM image with a second resolution that is lower than the first resolution for the pattern to be measured. According to one or more embodiments, the semiconductor pattern measurement device 100 may acquire an SEM image of the wafer surface region within a second FoV.

According to one or more embodiments, the semiconductor pattern measurement device 100 may acquire a SEM image of the wafer surface through the SEM 120 after acquiring a reference image. For example, an SEM image may have the second resolution that is lower than the first resolution of the reference image.

In the present disclosure, the SEM image may correspond to an SEM image with the second resolution (e.g., low resolution) for the wafer surface. For example, the second resolution may be lower than the first resolution.

In the present disclosure, the SEM image may correspond to an SEM image of a second region (e.g., a larger region) of the wafer surface. For example, the second region may have a second width in the first direction (e.g., first direction (X-axis direction) in FIG. 5) and/or the second direction (second direction (Y-axis direction) in FIG. 5). For example, the size of the second region may be dozens of times larger than the size of the first region. According to one or more other embodiments, the SEM image may correspond to the SEM image of the wafer surface region within the second FoV. For example, the second FoV may be dozens of times larger than the first FoV.

According to one or more embodiments, the semiconductor pattern measurement device 100 may determine the second resolution of the SEM image based on the reference repetition period (or target pitch) obtained from the reference image. According to one or more embodiments, the semiconductor pattern measurement device 100 may acquire an SEM image with a determined second resolution. For example, using the unit (nm) of the reference repetition period as the reference, the second resolution may be less than 1.5 times the reference repetition period. For example, when the reference repetition period is 30 nm, the second resolution may be smaller than 45 nm.

According to one or more embodiments, a moiré pattern may appear on an SEM image with the second resolution. Moiré effect may be caused by the repetitive pattern included in the pattern to be measured.

According to one or more embodiments, in operation 430, semiconductor pattern measurement device 100 may generate a first image by performing a two-dimensional Fourier transform on the SEM image.

According to one or more embodiments, the semiconductor pattern measurement device 100 may obtain the first image by performing a two-dimensional Fourier transform on SEM image data acquired through the SEM 120. According to one or more embodiments, the semiconductor pattern measurement device 100 may use a fast Fourier transform (FFT) method to calculate the phase of the peak. In the present disclosure, the first image may correspond to 2-dimensional FFT data obtained by performing 2-dimensional Fourier transform on the SEM image.

According to one or more embodiments, the semiconductor pattern measurement device 100 may acquire orientation information and/or periodicity information of a pattern to be measured based on the first image. For example, the semiconductor pattern measurement device 100 may analyze the first image to determine whether the pattern to be measured is composed of a repetitive pattern.

According to one or more embodiments, when the pattern to be measured is formed of a repetitive pattern, frequency components may be observed at a specific position on the first image. For example, the frequency component may include a pattern in the form of dots or lines. According to one or more embodiments, the first image may include a plurality of frequency components having a two-dimensional array centered on the midpoint. In addition, the first image may have symmetry with respect to the midpoint.

According to one or more embodiments, the semiconductor pattern measurement device 100 may acquire directionality and/or periodicity information of a pattern to be measured based on the first image. For example, when the pattern to be measured has periodicity, symmetrical frequency components may be detected using the midpoint as a reference in the first image. For example, in the case of a repetitive pattern that repeats with a specific period in the first direction (X-axis direction), frequency components may be detected on the X-axis. In addition, for example, in the case of a repetitive pattern that repeats with a specific period in the second direction (Y-axis direction), frequency components may be detected on the Y-axis.

According to one or more embodiments, in operation 440, the semiconductor pattern measurement device 100 may generates a second image by merging a plurality of first images.

According to one or more embodiments, the semiconductor pattern measurement device 100 may generate aliasing by using an undersampling method. When using the undersampling method, an input signal frequency exceeds the boundary of the Nyquist frequency, and thus the semiconductor pattern measurement device 100 according to one or more embodiments reconstructs the first image to determine the exact position of the peak, thereby generating a second image.

According to one or more embodiments, the semiconductor pattern measurement device 100 may generate the second image by merging a plurality of first images in order to detect peaks generated by the repetitive pattern of the pattern to be measured. For example, the semiconductor pattern measurement device 100 may generate the second image by merging the same first images. For example, the semiconductor pattern measurement device 100 may generate identical first images by copying one first image. In the present disclosure, the second image may correspond to two-dimensional FFT data that is a merge of the same first images.

According to one or more embodiments, the semiconductor pattern measurement device 100 may merge the same first images. For example, the semiconductor pattern measurement device 100 may merge multiple first images using a stitching method. For example, the semiconductor pattern measurement device 100 may generate the second image by connecting the boundary of the first image. For example, the second image may correspond to data created in a 3×3 format by merging the nine first images using a stitching method.

According to one or more embodiments, in operation 450, the semiconductor pattern measurement device 100 may calculate the repetition period of the repetitive pattern in the second image based on information about the reference repetition period of the repetitive pattern obtained from the reference image.

According to one or more embodiments, the semiconductor pattern measurement device 100 may estimate a position of the peak on the second image based on the reference image stored in the memory 130. For example, the semiconductor pattern measurement device 100 may estimate the position of the peak on the second image based on the reference repetition period (or target pitch) stored in the memory 130.

Since frequency is defined as 1/period, the semiconductor pattern measurement device 100 may calculate the frequency corresponding to the reciprocal of the target pitch and search a region near the calculated frequency on the second image.

According to one or more embodiments, the semiconductor pattern measurement device 100 may calculate the repetition period (or pitch) of the repetitive pattern using the frequency corresponding to the detected peak. Since the period is defined as 1/frequency, the period corresponding to the reciprocal of the frequency may be calculated. For example, the semiconductor pattern measurement device 100 may calculate the X-axis pitch (Pₓ) in the first direction (X-axis direction) and/or the Y-axis pitch (P_{y}) in the second direction (Y-axis direction) for the repetitive pattern based on the phase of the peak detected from the second image. Details related to calculating the pitch of the repetitive pattern will be described later with reference to FIG. 9.

According to one or more embodiments, the semiconductor pattern measurement device 100 may repeats the operations of FIG. 4 until accurate data on the position or shape of the peak is obtained. For example, the semiconductor pattern measurement device 100 may return to the operation 420 of FIG. 4 after acquiring information about the repetition period in operation 450 and perform operations following the operation 420 repeatedly. In this case, a region of the pattern to be measured may change. For example, the semiconductor pattern measurement device 100 may detect the peak for the changed region of the measurement target pattern while changing the region of the measurement target pattern after acquiring information about the repetition period.

As described above, in the semiconductor pattern measurement device according to one or more embodiments, the accuracy of peak detection may be improved by changing the region of the pattern to be measured and repeating the operations 420 to 450.

FIG. 5 shows a reference image of a surface of a wafer where a measurement target pattern is formed according to one or more embodiments.

Referring to FIG. 5, a semiconductor pattern measurement device (e.g.: the semiconductor pattern measurement device 100 of FIG. 1) according to one or more embodiments may acquire an image on a wafer through an SEM (e.g.: the SEM 120 of FIG. 1). According to one or more embodiments, the SEM 120 may acquire a reference image 500 corresponding to the first FoV (e.g., a local region) and a first resolution (e.g., high resolution) for the pattern to be measured formed on the wafer surface.

According to one or more embodiments, the reference image 500 may include measurement target patterns 510 and 520 formed of repetitive patterns. For example, the measurement target pattern may include at least one of a first pattern 510 or second pattern 520. The first pattern 510 and the second pattern 520 may overlap on the reference image 500.

For example, each repetitive pattern that forms the measurement target pattern may be formed of a line or circle shape. However, embodiments are not limited thereto, and the shape of the repetitive pattern forming the measurement target pattern may be changed according to various embodiments. For example, the repetitive pattern may be formed of a bar shape. For example, the repetitive pattern may be formed of a bar shape with a slope in one direction.

According to one or more embodiments, the first pattern 510 may correspond to a pattern in which a straight line shape is repeated in the first direction (X-axis direction). According to one or more embodiments, the first pattern 510 may be arranged such that the centers along the first direction (X-axis direction) match. According to one or more embodiments, the first pattern 510 may be arranged to have a first pitch P1ₓ along the first direction (X-axis direction). According to one or more embodiments, the first pattern 510 may not be repeatedly arranged in the second direction (Y-axis direction).

According to one or more embodiments, the second pattern 520 may correspond to a pattern in which a circular shape is repeated in the first direction (X-axis direction) and the second direction (Y-axis direction). According to one or more embodiments, the second pattern 520 may be arranged such that the centers along the first direction (X-axis direction) match. In addition, the second pattern 520 may be arranged such that the centers along the second direction (Y-axis direction) match. According to one or more embodiments, the second pattern 520 may be arranged to have a second pitch P2ₓ along the first direction (X-axis direction) and a third pitch P2_{y} along the second direction (Y-axis direction).

According to one or more embodiments, information about the first pitch P1ₓ of the first pattern 510 may be stored in a memory (e.g., the memory 130 in FIG. 1) as reference period information (or target pitch) of the first pattern 510. In addition, information about the second pitch P2ₓ and the third pitch P2_{y} of the second pattern 520 may be stored in memory 130 as reference period information (or target pitch) of the second pattern 520.

According to one or more embodiments, the reference repetition period stored in the memory 130 for the measurement target patterns 510 and 520 may be used to detect peak positions of the measurement target patterns 510 and 520, which will be described later with reference to FIG. 9.

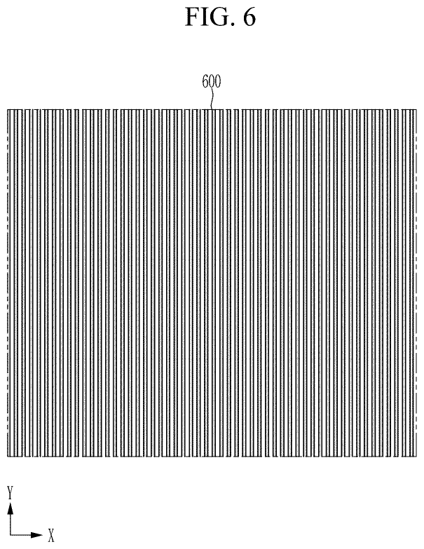

FIG. 6 shows an SEM image on a wafer surface where a measurement target pattern is formed according to one or more embodiments.

Referring to FIG. 6, a semiconductor pattern measurement device (e.g.: the semiconductor pattern measurement device 100 of FIG. 1) according to one or more embodiments may obtain an image on a wafer through an SEM (e.g.: the SEM 120 of FIG. 1). According to one or more embodiments, the SEM 120 may obtain an SEM image 600 corresponding to a second FoV (e.g., large area) and a second resolution (e.g. low resolution) for the measurement target pattern formed on the wafer surface.

According to one or more embodiments, the SEM image 600 may correspond to an SEM image of a wafer surface region within the second FoV. For example, the second FoV may be greater than or equal to several dozen times than the first FoV corresponding to the region where the reference image 500 is acquired.

According to one or more embodiments, the SEM image 600 may have a second resolution lower than the first resolution of a reference image (e.g., reference image 500 in FIG. 5).

According to one or more embodiments, the semiconductor pattern measurement device 100 may determine a second resolution based on a reference repetition period (or target pitch). According to one or more embodiments, the semiconductor pattern measurement device 100 may acquire the SEM image 600 with a determined second resolution. For example, using the unit (nm) of the reference repetition period as the reference, the second resolution may be less than 1.5 times the reference repetition period. For example, when the target pitch is 30 nm, the second resolution may be less than 45 nm.

According to one or more embodiments, the SEM image 600 may include a moiré pattern generated by a repetitive pattern. The moiré phenomenon is a phenomenon in which a wave pattern is observed, which is caused by the overlap of two or more periodic wave patterns due to the interference phenomenon of light according to the wave nature of light. According to the present disclosure, the moiré phenomenon may occur due to a measurement target pattern consisting of a repetitive pattern.

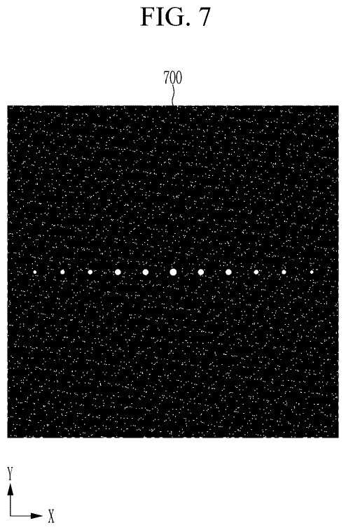

FIG. 7 shows a first image obtained by performing a two-dimensional Fourier transform on the SEM image of FIG. 6.

According to one or more embodiments, a semiconductor pattern measurement device (e.g.: the semiconductor pattern measurement device 100 of FIG. 1) may use a fast Fourier transform (FFT) method for calculation of the peak phase. According to one or more embodiments, a first image 700 may correspond to 2-dimensional FFT data obtained by performing the two-dimensional Fourier transform on an SEM image (e.g., the SEM image 600 in FIG. 6).

According to one or more embodiments, the semiconductor pattern measurement device 100 may acquire at least one of directionality information or periodicity information of the measurement target pattern based on the first image 700. For example, the semiconductor pattern measurement device 100 may analyze the first image 700 to determine whether the measurement target pattern is formed of a repetitive pattern.

According to one or more embodiments, due to the characteristic of the repetitive pattern, a specific frequency component corresponding to a pattern repeated in the first direction (X-axis direction), the second direction (Y-axis direction), or any direction may be observed in the first image 700. For example, the frequency component may be observed in the form of dots or lines.

For example, the center of the first image is a point with space frequency 0, which may indicate the DC component. The higher the frequency, the further away the frequency component is from the center, and the lower the frequency, the closer the frequency component may be positioned to the center. For repetitive patterns, as shown in FIG. 7, a pattern in the form of a dot or line may be observed at a specific position.

For example, in the case of a repetitive pattern that repeats with a specific cycle in the first direction (X-axis direction), the repetitive pattern may be displayed as a dot on the X-axis.

In addition, for example, in the case of a repetitive pattern that repeats with a specific cycle in the second direction (Y-axis direction), the repetitive pattern may be displayed as a dot on the Y-axis. In addition, for example, in the case of a repetitive pattern that repeats with a specific cycle in the first direction (X-axis direction) and the second direction (Y-axis direction), it is displayed as a dot on an arbitrary axis between the X-axis and the Y-axis. For example, an arbitrary axis may be defined as an axis forming a predetermined angle with the X-axis or Y-axis.

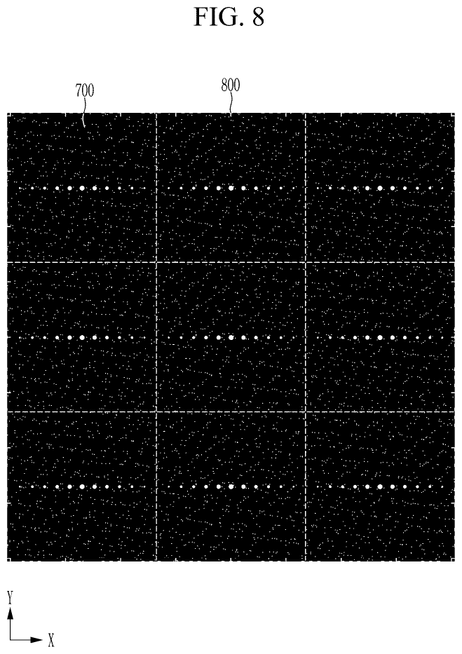

FIG. 8 shows a second image obtained by merging a plurality of the first image of FIG. 7.

In a sampling theory, input signal frequencies exceeding the Nyquist frequency are aliased. For example, the input signal frequencies are replicated to other positions in the spectrum above or below the Nyquist frequency. Aliasing may be used advantageously in cases of undersampling.

According to one or more embodiments, the semiconductor pattern measurement device 100 may generate aliasing by using an undersampling method. When using the undersampling method, the frequency corresponding to the position of the peak exceeds the boundary of the Nyquist frequency, and thus the semiconductor pattern measurement device 100 according to one or more embodiments reconstructs the first image 700 to determine the exact position of the peak to thereby generate the second image 800.

According to one or more embodiments, the semiconductor pattern measurement device 100 may generate (or acquire) the second image 800 by reconstructing a plurality of first images 700 by merging them. According to one or more embodiments, the semiconductor pattern measurement device 100 may merge the plurality of first images 700 using a stitching method. The stitching method may be a method of connecting the boundaries of images. For example, as shown in FIG. 8, the semiconductor pattern measurement device 100 may merge the first image 700 into a 3×3 format using the stitching method.

FIG. 9 shows a position of a peak generated by the repetitive pattern of the measurement target pattern according to one or more embodiments.

According to one or more embodiments, the semiconductor pattern measurement device 100 may calculate a repetition period (or, pitch) of a repetitive pattern based on the second image 800. For example, the semiconductor pattern measurement device 100 according to one or more embodiments may detect the peak position on the second image based on the previously stored reference repetition period (or target pitch) for the repetitive pattern. For example, the reference repetition period may be obtained from a reference image (e.g., reference image 500 in FIG. 5) and previously stored. According to one or more other embodiments, for example, the reference repetition period may be input by a user (e.g. worker) and pre-stored. However, embodiments are not limited thereto, and information about the reference repetition period may be pre-stored according to various embodiments.

According to one or more embodiments, the semiconductor pattern measurement device 100 may estimate the position of the peak on the second image 800 based on the reference repetition period (or target pitch). Since frequency is defined as 1/period, the semiconductor pattern measurement device 100 may calculate the frequency corresponding to the reciprocal of the reference repetition period and search a region near the frequency calculated on the second image 800.

Referring to FIG. 9, the semiconductor pattern measurement device 100 may detect a peak of a first pattern (e.g.: the first pattern 510 of FIG. 5) in a first region 901. The first region 901 may be a region of which peak coordinates correspond to (−1/P1ₓ, 0) and (1/P1ₓ, 0). According to one or more embodiments, in the semiconductor pattern measurement device 100, the peak coordinates are detected as (−1/P1ₓ, 0) and (1/P1ₓ, 0), and thus it may be determined that the first pattern 510 is arranged repeatedly in the first direction (X-axis direction).

Referring to FIG. 9, the semiconductor pattern measurement device 100 may detect a peak of a second pattern (e.g.: the second pattern 520 of FIG. 2) in a second region 902. Peak coordinates of the second region 902 may be a region corresponding to (−1/P2ₓ, 1/P2_{y}), (1/P2ₓ, 1/P2_{y}), (−1/P2ₓ, −1/P2_{y}), and (1/P2ₓ, −1/P2_{y}). According to one or more embodiments, in the semiconductor pattern measurement device 100, the peak coordinates are detected as (−1/P2ₓ, 1/P2_{y}), (1/P2ₓ, 1/P2_{y}), (−1/P2ₓ, −1/P2_{y}), and (1/P2ₓ, −1/P2_{y}), and thus it is determined that the first pattern 510 is arranged repeatedly in the first direction (X-axis direction) and the second direction (Y-axis direction).

According to one or more embodiments, the semiconductor pattern measurement device 100 may calculate the period of the repetitive pattern using the frequency corresponding to the detected peak. For example, since the period is defined as 1/frequency, the period corresponding to the reciprocal of the frequency may be calculated.

According to one or more embodiments, the semiconductor pattern measurement device 100 may calculate the repetition period (or pitch) in the first direction (X-axis direction) based on the phase of the peak of the first pattern 510. According to one or more embodiments, the semiconductor pattern measurement device 100 may calculate the repetition period (or pitch) in the first direction (X-axis direction) and the second direction (Y-axis direction) based on the phase of the peak of the second pattern 520.

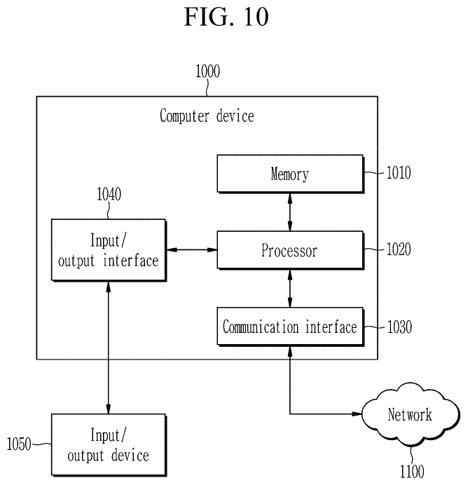

FIG. 10 shows a computer device that implements a semiconductor pattern measurement device according to one or more embodiments. The semiconductor pattern measurement device 100 of FIG. 1 may be implemented by a computer device 1000 shown in FIG. 10.

Referring to FIG. 10, the computer device 1000 may include a memory 1010, a processor 1020, a communication interface 1030, and an input/output interface 1040.

The memory 1010 is a recording medium readable by a computer and may include a permanent mass storage device such as a random access memory (RAM), a read only memory (ROM), and a disk drive. In addition, an operating system and at least one program code may be stored in the memory 1010. These software components may be loaded into the memory 1010 from a readable recording medium on a computer separate from the memory 1010. The recording medium that may be read by a separate computer may include recording medium that may be read by a computer, such as a hard disk, a flash memory, an optical disk, or an external hard disk. In addition, the software components may be loaded into the memory 1010 through a communication interface 1030.

The processor 1020 may be configured to process instructions of a computer program by performing basic arithmetic, logic, and input/output operations. Instructions may be provided to the processor 1020 by the memory 1010 or the communication interface 1030.

The communication interface 1030 may provide a function for the computer device 1000 to communicate with other devices through the network 1100. The communication method is not restrictive, and may include not only a communication method utilizing a communication network that the network 1100 may include (e.g., a mobile communication network, wired Internet, wireless Internet, or broadcasting network), but also short-distance wireless communication between devices. For example, the network 1100 may include one or more random networks among networks such as a personal area network (PAN), a local area network (LAN), a campus area network (CAN), a metropolitan area network (MAN), a wide area network (WAN), a broadband network (BBN), Internet, and the like. In addition, the network 1100 may include any one or more of network topologies including a bus network, a star network, a ring network, a mesh network, a star-bus network, a tree or hierarchical network, and the like, but is not limited thereto.

The input/output interface 1040 may serve as an interface that may transmit instructions or data input from the user or an input/output device 1050 to other component(s) of the computer device 1000. In addition, the input/output interface 1040 may output instructions or data received from other component(s) of the computer device 1000 to the user or the input/output device 1050. For example, the input/output device 1050 may include an input device such as a microphone, a keyboard, or a mouse, and the output device may include an output device such as a display or a speaker.

The embodiments described above may be implemented in the form of a computer program that may be executed on a computer through various configuration elements, and such a program may be recorded on a computer-readable medium. In this case, the medium is a magnetic medium such as a hard disk, a floppy disk, and a magnetic tape, an optical recording medium such as CD-ROM and DVD, a magneto-optical medium such as a floptical disk, and hardware devices For example configured to store and execute program instructions, such as a ROM, a RAM, a flash memory, and the like.

Unless there is a clear order or description to the contrary regarding the steps constituting the method according to the embodiment, the steps may be performed in an appropriate order. The present disclosure is not necessarily limited by the order of description of the steps.

All embodiments or use of terms in this specification are simply to describe the present disclosure in detail, and do not limit the scope of the present disclosure. In addition, those skilled in the art may recognize that various modifications, combinations, and changes may be made within the scope of the patent claims or their equivalents.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor pattern measurement method comprising:
obtaining a scanning electron microscope (SEM) image of a measurement target pattern on a surface of a wafer and comprising a repetitive pattern;
generating a first image by performing a two-dimensional Fourier transform on the SEM image;
generating a second image by merging a plurality of the first image; and
obtaining information on repetition period of the repetitive pattern based on the second image.

2. The semiconductor pattern measurement method of claim 1, further comprising, prior to the obtaining of the SEM image, obtaining a reference image having a first resolution corresponding to the measurement target pattern.

3. The semiconductor pattern measurement method of claim 2, wherein the obtaining the SEM image comprises obtaining the SEM image having a second resolution that is lower than the first resolution corresponding to the measurement target pattern.

4. The semiconductor pattern measurement method of claim 2, wherein the obtaining the SEM image comprises:
obtaining a resolution based on a reference repetition period obtained from the reference image; and
obtaining the SEM image having the obtained resolution.

5. The semiconductor pattern measurement method of claim 4, wherein the resolution of the SEM image is less than 1.5 times the reference repetition period.

6. The semiconductor pattern measurement method of claim 4, wherein the obtaining the information on the repetition period comprises:
estimating a position of a peak in the second image based on the reference repetition period; and
obtaining a peak of the repetitive pattern based on the estimated peak position.

7. The semiconductor pattern measurement method of claim 1, wherein the obtaining the information on the repetition period comprises:
obtaining a peak in the second image; and
obtaining the repetition period based on information of the obtained peak.

8. The semiconductor pattern measurement method of claim 1, wherein the generating the second image comprises merging the plurality of the first image in a 3×3 format based on a stitching method.

9. The semiconductor pattern measurement method of claim 1, further comprising, based on the obtaining the information on the repetition period, changing a region of the measurement target pattern and obtaining a peak for a region of the measurement target pattern for the changed region of the measurement target pattern.

10. A semiconductor pattern measurement method comprising:
obtaining a reference image having a first resolution corresponding to a measurement target pattern on a surface of a wafer and comprising a repetitive pattern;
obtaining a scanning electron microscope (SEM) image having a second resolution that is lower than the first resolution corresponding to the measurement target pattern;
generating a first image by performing a two-dimensional Fourier transform on the SEM image;
generating a second image by merging a plurality of the first image; and
obtaining a repetition period of the repetitive pattern in the second image based on information on a reference repetition period of the repetitive pattern obtained from the reference image.

11. The semiconductor pattern measurement method of claim 10, wherein:
the obtaining the SEM image comprises:
obtaining a second resolution based on a reference repetition period obtained from the reference image; and
obtaining the SEM image having the obtained second resolution.

12. The semiconductor pattern measurement method of claim 11, wherein the second resolution is less than 1.5 times the reference repetition period.

13. A semiconductor pattern measurement device comprising:
a scanning electron microscope (SEM) configured to obtain an SEM image on a surface of a wafer, on which a measurement target pattern comprising a repetitive pattern is formed; and
at least one processor operatively connected to the SEM,
wherein the at least one processor is configured to:
obtain an SEM image of the measurement target pattern on the surface of the wafer and comprising the repetitive pattern through the SEM,
generate a first image by performing a two-dimensional Fourier transform on the SEM image,
generate a second image by merging a plurality of the first image, and
obtain information on a repetition period of the repetitive pattern based on the second image.

14. The semiconductor pattern measurement device of claim 13, further comprising a memory,
wherein the at least one processor is further configured to:
obtain a reference image having a first resolution corresponding to the measurement target pattern prior to obtaining the SEM image; and
store the reference image in the memory.

15. The semiconductor pattern measurement device of claim 14, wherein the at least one processor is further configured to obtain the SEM image having a second resolution that is lower than the first resolution corresponding to the measurement target pattern.

16. The semiconductor pattern measurement device of claim 14, wherein the at least one processor is further configured to:
obtain a resolution based on a reference repetition period obtained from the reference image; and
obtain the SEM image having the obtained resolution.

17. The semiconductor pattern measurement device of claim 16, wherein the resolution of the SEM image is less than 1.5 times the reference repetition period.

18. The semiconductor pattern measurement device of claim 16, wherein the at least one processor is further configured to:
estimate a position of a peak in the second image based on the reference repetition period; and
obtain a peak of the repetitive pattern based on the estimated peak position.

19. The semiconductor pattern measurement device of claim 13, wherein the at least one processor is further configured to:
obtain a peak in the second image; and
obtain the repetition period based on information corresponding to the obtained peak.

20. The semiconductor pattern measurement device of claim 13, wherein the at least one processor is further configured to generate the second image by merging the plurality of the first image in a 3×3 format based on a stitching method.
